(19) United States
(12) Patent Application Publication
(10) Pub. No.: US 2009/0114951 A1
(43) Pub. Date: May 7, 2009

(54) MEMORY DEVICE

(75) Inventor: Bohumil Lojek, Colorado Springs, CO (US)

Correspondence Address: FISH & RICHARDSON P.C., PO BOX 1022, MINNEAPOLIS, MN, 55440-1022, US

(73) Assignee: ATMEL CORPORATION, San Jose, CA (US)

(21) Appl. No.: 11/936,460

(22) Filed: Nov. 7, 2007

(51) Int. Cl. H01L 27/115; H01L 21/82

(52) U.S. Cl. 257/202; 438/128; 257/E21.602; 257/E27.103

(57) ABSTRACT

A memory device can be implemented including word lines connected to an array of memory transistors. Each memory transistor is also connected to bit lines and a select transistor. The select transistors each have their sources connected to a conductive source line, by a shunt and the gate of each select transistor is connected to a select line.

### TECHNICAL FIELD

This document relates generally to the field of memory devices.

### BACKGROUND

Electronic devices are continually being developed that offer more performance while utilizing less power and in smaller packages. For example, portable computing devices have evolved into comprehensive data devices that integrate the features of phones, PDAs and computers. As the capabilities of these devices increase, so do their memory and power requirements. The increasing memory requirements of electronic devices coupled with shrinking power budgets and packaging dimensions requires memory devices that offer more storage, with lower power consumption, and smaller physical dimensions.

Source diffusion presents a challenge to such optimizations, however. Typically a region on the semiconductor substrate must be reserved to accommodate source diffusion regions. Accordingly, in some semiconductor devices, source diffusion may limit memory density.

### SUMMARY

Disclosed herein are memory devices and methods. The memory device can be implemented including word lines connected to an array of memory transistors. Each memory transistor is also connected to bit lines and a select transistor. The select transistors each have their source connected to a conductive source line, by a shunt and the gate of each select transistor is connected to a select line.

Implementations may include one or more of the following features and/or advantages. The highly conductive source line may enable a more dense memory array than realized with source diffusion by reducing spacing tolerances that are normally required for source diffusion. The conductive source line may also result in a lower impedance than realized with source diffusion. These features or advantages may be separately realized by one or more of the implementations described below. Other features and advantages of the invention will be apparent from the description and drawings, and from the claims.

### DESCRIPTION OF DRAWINGS

FIG. 1 is a circuit diagram of an example memory device.

FIG. 2 is a cross-section view of an embodiment of the memory device.

FIG. 3 is a perspective view of the embodiment of the memory device.

FIG. 4 is a circuit diagram illustrating the memory device in program mode.

FIG. 5 is a circuit diagram illustrating the memory device in erase mode.

FIG. 6 is a circuit diagram illustrating the memory device in read mode.

FIG. 7 is a flow diagram of an example process of manufacturing a memory device having a conductive source line.

Like reference symbols in the various drawings indicate like elements.

### DETAILED DESCRIPTION

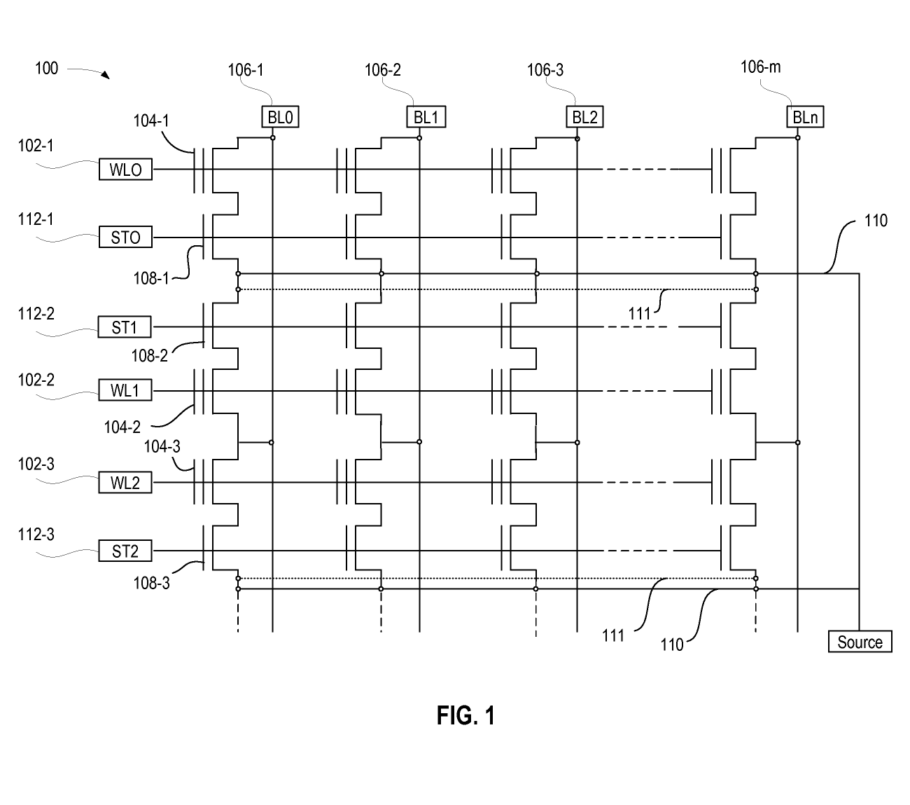

FIG. 1 is a circuit diagram of an example memory device 100. The example memory device 100 can include n word lines 102, of which the first three word lines 102-1, 102-2 and 102-3 are shown. The word lines 102 are arranged according to a matrix architecture, e.g., in parallel. Each word line 102 is respectively connected to a corresponding gate of a memory transistor 104, of which the first three memory transistors 104-1, 104-2 and 104-3 are shown. In one embodiment the memory transistors 104 can be MOSFET floating gate transistors. Other types of memory transistors, however, can also be used.

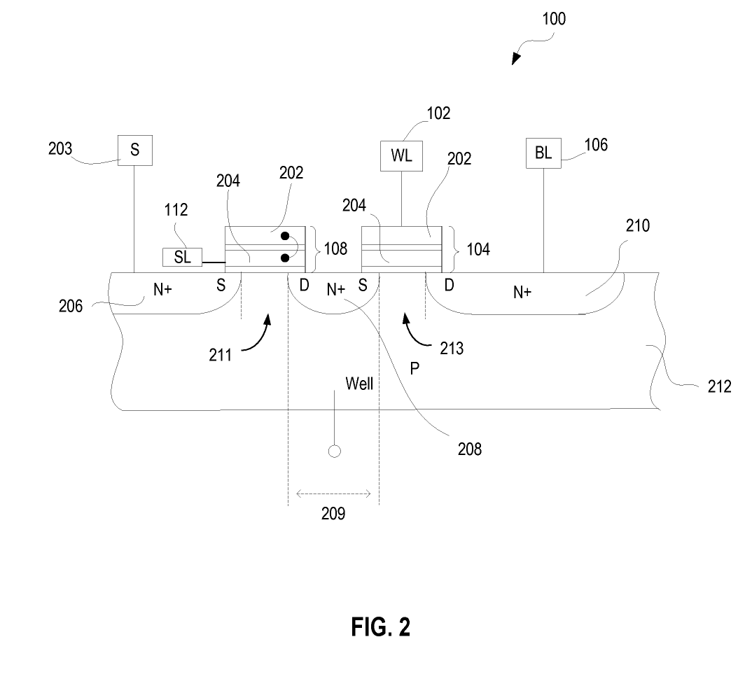

A first bit line 106-1 is connected to the memory transistors 104-1, 104-2 . . . 104-n. Each memory transistor 104, in turn, is connected to a corresponding select transistor 108. Accordingly, the memory device 100 includes n selector transistors, of which the first three select transistors are shown 108-1, 108-2 and 108-3 are shown. In an embodiment, the select transistors 108 can be a MOSFET floating gate transistor having the same physical structure as the memory transistors 104, but with the control gate bypassed, as shown in FIG. 2. Utilizing the same floating gate transistor for both the memory transistor 104 and the select transistor 108 allows the memory structure to be fabricated utilizing only one mask. Other types of select transistors, however, can also be used.

Bit lines 106-2 . . . 106-m are similarly connected to corresponding memory transistors and each memory transistor, in turn, is connected to select transistors, the numbering of which have been omitted to avoid congestion in the drawings. When configured in this manner, the memory transistors 104 that are connected to a common word line 102 may be programmed simultaneously, resulting in a row addressable memory array.

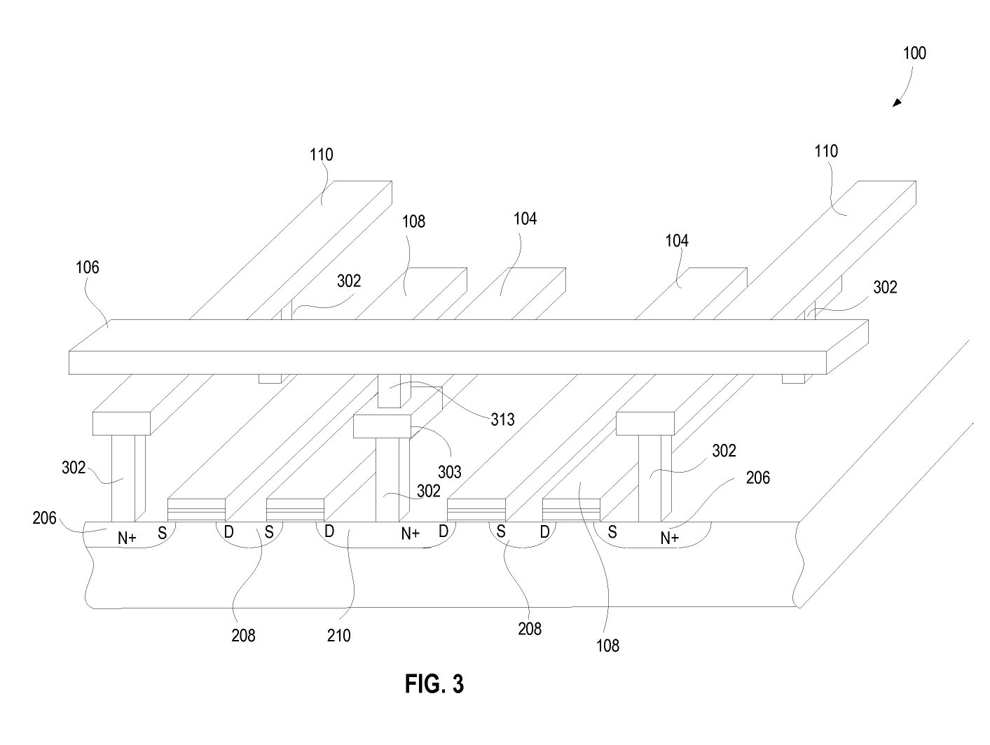

The example memory device 100 can also include n select lines 112, of which the first three select lines 112-1, 112-2 and 112-3 are shown. The select lines 112-1, 112-2 . . . 112-n are arranged according to the matrix architecture, e.g. in parallel and corresponding to respective word lines 102-1, 102-2 . . . 102-n. Each select line 112 is respectively connected to a corresponding gate of a select transistor 108, and each of the select transistors 108 has its source connected to a conductive source line 110. The conductive source line 110 can be tungsten, titanium, nickel, or any other suitable conductive metal and can have lower impedance than that realized by a diffusion line or a diffusion region metallized layer 111. Additionally, the metallized source line 110 facilitates a more dense memory array, as will be described with respect to FIGS. 2 and 3.

In some implementations the conductive source line 110 can be connected in parallel with the diffusion region metallized layer 111 that is, in turn, connected to a subset of the select transistors 108. The subset of the select transistors 108 connected to the diffusion region metallized layer 111 can vary according to the resistivity of the diffusion region metallized layer 111. In these implementations the conductive source line 110 can have lower impedance than that realized by the diffusion region metallized layer 111.

FIG. 2 is a cross-section view of an embodiment of the memory device 100. Two floating gate MOSFETs are shown, each having a control gate 202, a floating gate 204, N+ regions 206, 208 and 210 forming the sources and the drains of the devices, and a body 212. A word line 102 is connected to the control gate 202 of the memory transistor 104. A bit line 106 is connected to the N+ region 210 defining the drain of the memory transistors 104.

The select transistor 108 is implemented having its control gate 202 and floating gate 204 connected to form the select line 112. This allows the select transistor 108 to be fabricated as a floating gate transistor, but operated as a single gate transistor. Fabricating both the memory transistor 104 and the select transistor 108 as floating gate transistors enables manufacturing to be performed with only one gate mask, thereby simplifying the manufacturing process. The source of the select transistor 108 is formed by N+ region 206, and the body 212 is shown as a P region. A well region 209 is formed by the area within the body 212 below the N+ region 208 common to the select transistor 108 and the memory transistor 104.

The gates 202 and 204 of the device may be constructed of polysilicon or other appropriate conductive gate material. The N+ regions 206, 208 and 210 may be formed in any appropriate semiconductor material, for example, silicon or any appropriate semiconductor material, and can be created by introducing dopants into regions of the silicon and activating these dopants through an annealing process. However, during this annealing process, the high temperatures utilized to activate the N+ dopants will cause the dopants to redistribute by diffusing through the body 212 creating larger N+ doped regions 206, 208 and 210.

Diffusion region conductivity is inversely related to the level of doping implanted in the semiconductor material. Therefore, to achieve higher conductivity, more doping is required. However, implanting more doping results in higher diffusion during the annealing process which, in turn, leads to larger diffusion regions 206, 208, and 210. Conversely, while smaller diffusion regions can be achieved by utilizing a lower level of doping, this results in a higher resistance and capacitance, thereby lowering the current that will flow through the diffusion regions at a given voltage. A higher resistance is particularly problematic in the diffusion region 206 because during the read operation current flowing from the source to the drain of the memory transistor 104 is measured by a sensing amplifier to determine whether the memory transistor is programmed as a “0” or a “1”. As a result, a higher source diffusion resistance requires higher voltages to generate the desired read current.

A high level of doping can limit the density of a memory array, as the lateral diffusion region also determines the channel length of the transistors on the substrate. For example, diffusion regions 206, 208 and 210 define the boundaries of undoped channels 211 and 213 located beneath the gates of the transistors, as shown in FIG. 2. Proper operation of the transistors requires that a minimum channel length be maintained. When a large diffusion region is formed, greater spacing between the gates of adjacent transistors is required to maintain this required channel length. Therefore, the larger the diffusion region is, the larger the substrate area required for the memory device.

As shown in FIG. 1, the memory transistors 104 and the selector transistors 108 are adjacently connected, e.g., the drains of respective memory transistors 104 are connected, and the sources of respective select transistors 108 are connected. Utilization of the conductive source line 110 results in a lower source impedance than that realized through a source diffusion region, and thus lower voltages can be utilized to generate the same read current. Additionally, the conductive source line 110 facilitates closer spacing of the select transistors 108 that are adjacently connected to the conductive source line 110, e.g., select transistors 108-1 and 108-2 of FIG. 1, as the amount of doping required for this diffusion region 206 can be reduced. This reduction in doping results in a smaller diffusion region underneath the gate and, in turn, a greater scaling of transistors can be achieved. Thus, the larger channels 211 and 213 allow for a more densely spaced memory array while maintaining the minimum channel length.

FIG. 3 is a perspective view of an example embodiment of the memory device 100. This view shows memory transistors 104 and select transistors 108 having N+diffusion regions 206, 208 and 210 defining the source and drain connections of the transistors 104 and 108. The conductive source lines 110 are shown connected to the source diffusion regions 206 by shunts 302. The shunts 302 can be formed from tungsten, titanium, nickel, or any other suitable conductive metal and are proximately spaced throughout the diffusion region of select transistors that share a select line 112. The conductive source lines 110 define the source line for each of the select transistors 108 and are connected to the select transistors 108 by the source diffusion region 206. The bit line 106 is shown as a conductive line and connected to the drain diffusion region 210 which is common to the memory transistors 104. The bit line is connected to the diffusion region 206 by a shunt 302, and a pad 303.

The conductive source lines 110 facilitate the conduction of source current. The conductive source lines 110 have lower resistance and capacitance than the source diffusion regions 206. Therefore, the conductive source line 110 facilitates the conduction of more current at lower voltages than a diffusion region 206. Additionally, the lower capacitance of the conductive source line 110 also results in lower capacitive coupling with other lines in the memory device 100. Thus, utilizing the conductive source line 110 allows the source diffusion region 206 to be smaller because the source diffusion region 206 current capacity requirements are reduced. Accordingly, less doping material can be used, resulting in lower diffusion. The lower diffusion allows for a larger channel 211 and 213 resulting in proper gate operation for transistors that are spaced more closely than would otherwise be possible. This results in a more dense memory device 100 which is capable of being utilized in smaller devices with lower power consumption.

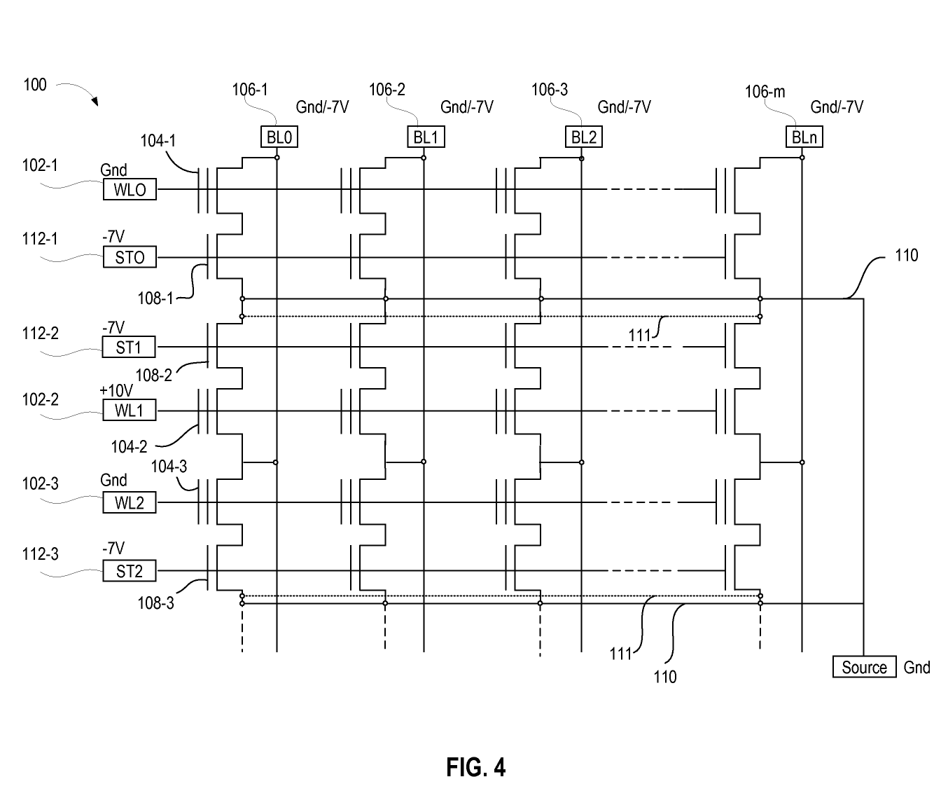

FIGS. 4-6 illustrate the various operational mode voltage requirements facilitated by the conductive source line 110. FIG. 4 is a circuit diagram illustrating the memory device 100 in program mode. To program the memory transistors 104 connected to the word line 102-2, each of the select transistors 108-1-108-n has a negative voltage applied to its floating gate while a reference voltage, e.g. ground, is applied to the source of the select transistors 108 through the source line 110 to keep the select transistors 108 off. Meanwhile, a positive voltage is applied to the word line 102 that is connected to the control gate 202 of the memory transistors 104 to be programmed while either a reference voltage, e.g., ground, or a negative voltage is applied to the bit lines 106-1-106-m in order to program the memory transistor 104 as high or low, respectively.

For example, a voltage of +10V can be applied to the word line 102-2, a voltage of −7V can be applied to the select line 112-2, and the source line 110 can be grounded. In this operational mode, a memory transistor 104 can be programmed by applying a voltage of −7V to a corresponding bit line 106. Applying ground to a bit line 106, however, results in the memory transistor 104 maintaining a current state. Normally, a larger voltage such as −12V would be required to program the memory transistors 104 because of the capacitive coupling between the bit lines 106 and the source diffusion region 206; however, the lower capacitance of the conductive source line 110 results in less capacitive coupling between the bit lines 106 and the conductive source line 110, which, in turn, results in less programming pulse loss. Therefore, a lower programming pulse magnitude can program the memory transistors 104. While voltage magnitudes are provided to demonstrate the program mode operation, other voltage magnitudes can be used to accommodate manufacturing or operational preferences.

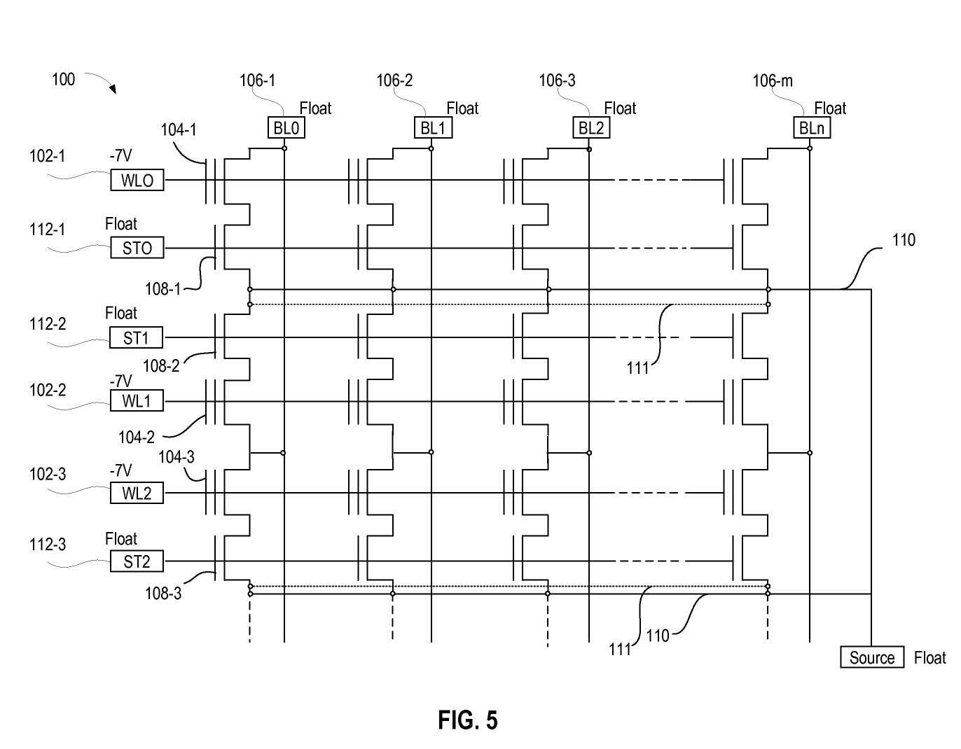

FIG. 5 is a circuit diagram illustrating the memory device 100 in erase mode. Each of the select lines 112-1-112-n, bit lines 106-1-106-m and the source line 110 are floating. To erase memory transistors sharing a common well, e.g., transistors 104-2 and 104-3, a voltage of +10V is applied to the well 209, and each of the word lines 102-1 and 102-2 are coupled to a voltage of −7V. Electrons are thus forced from the floating gates 204 back into the channel of the MOSFET, resulting in erased memory transistors 104. While voltage magnitudes are provided to demonstrate the erase mode operation, other voltage magnitudes can be used to accommodate manufacturing or operational preferences.

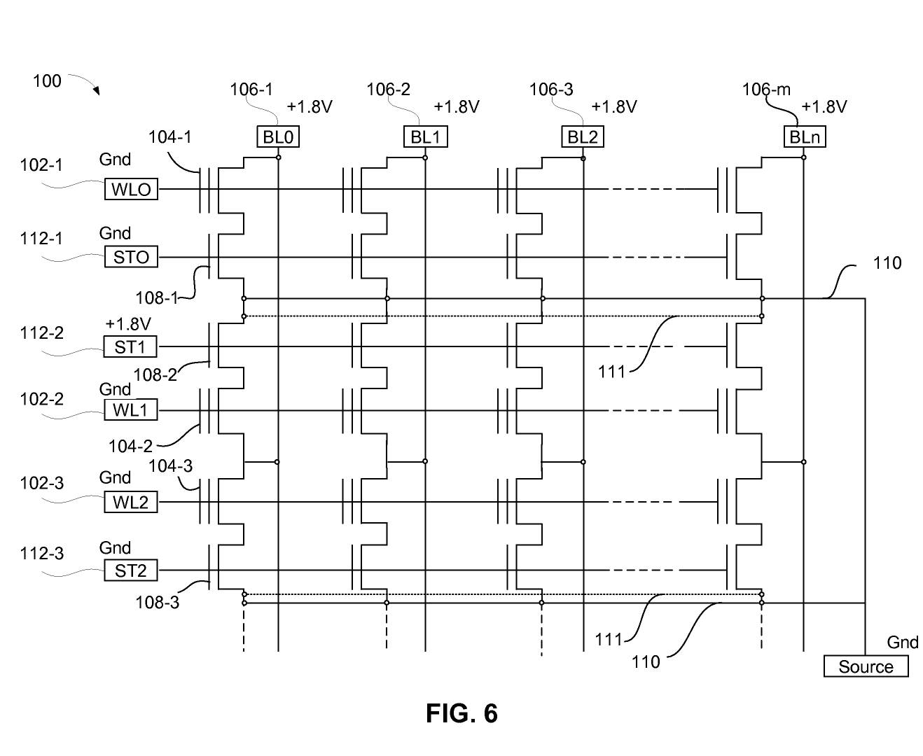

FIG. 6 is a circuit diagram illustrating the memory device 100 in read mode. To read memory transistors 104, each of the word lines 102-1-102-n and the source line 110 are connected to ground. A voltage of +1.8V is applied to the bit lines 106-1-106-m, and the select line 112-2 associated with the word line 102-2 to be read also has an applied voltage of +1.8V. This results in the select transistors 108-2 being biased on and the memory transistor 104-2 being biased on to allow current to flow. The drain current of the memory transistor 104-2 is detected to determine whether the memory transistor 104-2 is in a state representing logic “0” or in a state representing logic “1”. The memory transistor 104 can be read by applying lower voltages than normally required because the conductive source line 110 has lower impedance than the diffusion region and therefore a higher current can be realized at lower voltages. While voltage magnitudes are provided to demonstrate the erase mode operation, other voltage magnitudes can be used to accommodate manufacturing or operational preferences.

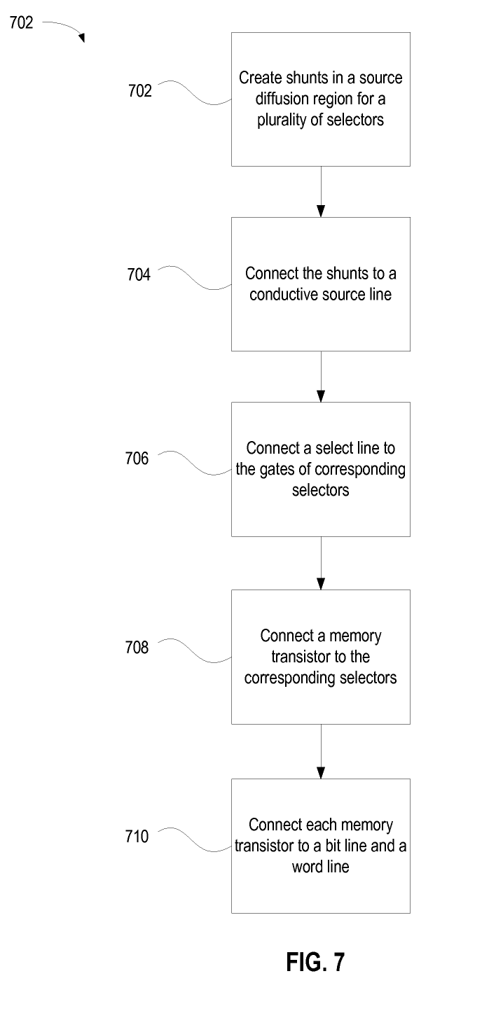

FIG. 7 is a flow diagram of an example process of manufacturing a memory device having a conductive source line. The process 700 can be used to manufacture the device 100 described above, or other memory devices having conductive source lines.

Stage 702 creates shunts in the source diffusion region for a plurality of selectors. An example selector can be a MOSFET floating gate transistor that can be manufactured by utilizing a mask to form polysilicon gates on a semiconductor substrate that has doped regions defining the source and drain contacts of the MOSFET. The shunts can be manufactured from tungsten, titanium, nickel, aluminum, a conductive polymer, or any other suitable conductive metal. The source diffusion can be formed by implanting dopants into the body of a semiconductor and activating the dopants through an annealing process. For example, select transistors 104 in FIG. 3 can be manufactured by utilizing a mask to form gates on top of the body 212 which has doped regions 206, 208, and 210. The mask is positioned over the diffusion regions 206 and 208. The diffusion regions 206 and 208 define the source and drain connections of the select transistor 108, respectively. Shunts 302 can be connected to the diffusion region 206 for the select transistors 108.

Stage 704 connects the shunts to a conductive source line. The conductive source line can be manufactured from tungsten, titanium, nickel, aluminum, a conductive polymer or any other suitable conductive metal. For example, conductive source line 110 in FIG. 3 can be placed on top of the shunts 302 during manufacturing to connect the source of the select transistor 108 to the conductive source line 110. Additionally during this stage, a pad 303 can be connected to the shunt 302 that is connected to the diffusion region 210 to facilitate further manufacturing processes.

Stage 706 connects a select line to the gates of corresponding selectors. The select line can be connected to the gate of a single gate transistor or it can be connected to the floating gate of a floating gate transistor. For example, select line 112 in FIG. 2 is connected to the floating gate 204 of the select transistor 108. Connecting the select line 112 to the floating gate 204 results in an inoperable control gate 202 allowing the select transistor 108 to operate as a single gate transistor.

Stage 708 connects a memory transistor to the corresponding selectors. The memory transistors and the selectors can be manufactured as floating gate transistors. Manufacturing both transistors as floating gate transistors enables simplification of the manufacturing process because both transistors can be manufactured utilizing a single mask. For example, select transistor 108 and memory transistor 104 in FIG. 2 are manufactured as floating gate transistors having a control gate 202 and a floating gate 204. Memory transistor 104 is manufactured by utilizing a mask to form the gates of the memory transistors 104 on the body 212. During manufacturing the mask is positioned over the diffusion regions 208 and 210 which define the source and drain of the memory transistor 104, respectively.

Stage 710 connects each memory transistor to a bit line and a word line. The bit line can be manufactured as a conductive line and connected to the drain of the memory transistors. For example, the conductive bit line 106 in FIG. 3 can be connected to the memory transistor 104. A shunt extension 313 can be placed on top of the pad 303 and then the conductive bit line 106 can be placed on top of the shunt 313. The shunt 302, pad 303, and shunt extension 313 create a conductive path from the conductive bit line 106 to the drain of the memory transistors 104.

Additionally, the memory transistors can be manufactured as a polysilicon control gate and connected to a word line. For example, memory transistor 104 in FIG. 2 has its control gate 202 connected to a word line 102. Connecting the word line 102 to the control gate 202 facilitates the biasing of each memory transistor 104, sharing the control gate 202 similarly, thereby enabling an entire word of memory to be read simultaneously.

In some implementations, the conductive source line 110 can comprise a material other than metal. For example, a conductive polymer or some other material that provides a similar and/or higher conductance and lower impedance than a source diffusion region can also be used.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art may effect alterations, modifications and variations to the examples without departing from the scope of the invention.

What is claimed is:

1. A memory device, comprising:
a plurality of word lines;
a plurality of memory transistors connected to each word line;
a plurality of bit lines, each bit line connected to at least one memory device on each word line;
a plurality of selectors, each selector including a source, a gate, and a drain, connected to a corresponding memory transistor;
a conductive source line connected to the source of each of the plurality of selectors; and
a plurality of select lines, each select line connected to the gates of the plurality of selectors.

2. The memory device of claim 1, wherein the select transistors define a source diffusion region, and further comprising a plurality of proximately spaced shunts, wherein each shunt connects the source diffusion region to the conductive source line.

3. The memory device of claim 1, wherein the plurality of memory devices are floating gate devices.

4. The memory device of claim 1, wherein the conductive source line comprises:
a tungsten plug; and
a conductor, wherein the conductor is either aluminum or copper.

5. The memory device of claim 1, wherein the plurality of selectors are select transistors having a control gate connected to a floating gate.

6. The memory device of claim 5, wherein each floating gate device has a floating gate connected to the select line.

7. A method, comprising:
creating shunts in a source diffusion region for a plurality of selectors, each selector having a source, a gate, and a drain;
connecting the shunts to a conductive source line;
connecting a select line to the gates of corresponding selectors;
connecting a memory transistor to the corresponding selectors; and
connecting each memory transistor to a bit line and a word line.

8. The method of claim 7, wherein the shunting is proximately spaced throughout the source diffusion region.

9. The method of claim 7, wherein connecting the plurality of selectors comprises connecting a plurality of floating gate devices to the conductive source line.

10. The method of claim 7, wherein connecting the select line to the gate comprises connecting the select line to a floating gate of each of the plurality of selectors.

11. The method of claim 7, wherein the conductive source line is connected in parallel with a metallized source layer.

12. The method of claim 7, wherein the conductive source line comprises aluminum.

13. A memory device comprising:
an array of memory transistors connected to a word line;
a plurality of bit lines, each bit line connected a corresponding memory transistor on the word line;
a corresponding selector connected to each corresponding memory transistor, each corresponding selector having a source, a gate, and a drain and defining a source diffusion region;
a select line connected to the gate of each of the corresponding selectors; and
a conductive source line connected to the source diffusion region of each selector by proximately spaced shunts.

14. The device of claim 13, wherein the memory transistors are floating gate type transistors.

15. The device of claim 13, wherein the conductive source line is connected in parallel with a metallized source layer.

16. The device of claim 13, wherein the conductive source line is a conductive polymer.

17. The device of claim 13, wherein the selector is a floating gate transistor.

18. The device of claim 17, wherein the select line is connected to a floating gate of the selector.

19. A memory device, comprising:
a plurality of word lines and a plurality of memory transistors connected to each word line;
a plurality of bit lines, each bit line connected to at least one memory device on each word line;
a plurality of adjacently connected selectors, each adjacently connected selector in turn connected to a corresponding memory transistor;
a plurality of select lines, each select line connected to the gates of the plurality of selectors; and
means for adjacently connecting the plurality of selectors in a diffusion region.
